(19) United States
(12) Patent Application Publication
(10) Pub. No.: US 2024/0250502 A1
(43) Pub. Date: Jul. 25, 2024

(54) METHOD FOR MANUFACTURING VERTICAL CAVITY SURFACE EMITTING LASER DEVICE

(71) Applicant: INOPTIX Inc., Jeollabuk-do (KR)

(72) Inventors: Gyeong Cheol PARK, Daejeon (KR); Sae Kyoung KANG, Daejeon (KR)

(21) Appl. No.: 18/532,766

(22) Filed: Dec. 7, 2023

(30) Foreign Application Priority Data
Jan. 19, 2023 (KR) 10-2023-0007822
Jun. 29, 2023 (KR) 10-2023-0084421

(51) Int. Cl. H01S 5/183; H01S 5/02; H01S 5/227

(52) U.S. Cl. CPC H01S 5/18344; H01S 5/0215; H01S 5/0217; H01S 5/2275; H01S 5/021

(57) ABSTRACT

Disclosed is a method for manufacturing a vertical-cavity surface-emitting laser device. The methods includes forming an etch stop layer, a first reflective layer, a first spacer layer, an active layer, an electron barrier layer, a tunnel junction layer, and a dummy current restriction layer on a carrier substrate, forming a dummy current restriction pattern having an opening by partially removing the current restriction layer using a photolithography process and an etching process, forming a second spacer layer in the opening and on the current restriction pattern, bonding the second spacer layer onto a substrate having a second reflective layer, and removing the carrier substrate and the etch stop layer.

### CROSS-REFERENCE TO RELATED APPLICATIONS

This U.S. non-provisional patent application claims priority under 35 U.S.C. § 119 of Korean Patent Application Nos. 10-2023-0007822, filed on Jan. 19, 2023, and 10-2023-0084421, filed on Jun. 29, 2023, the entire contents of which are hereby incorporated by reference.

### BACKGROUND

The present disclosure herein relates to a method for manufacturing a vertical-cavity surface-emitting laser device, and more particularly, to a method for manufacturing a long-wavelength vertical-cavity surface-emitting laser device.

In the case of typical vertical-cavity surface-emitting lasers (VCSEL) based on GaAs material for an NIR wavelength band light source, an oxide opening forming method has been introduced in order to increase the efficiency of VCSEL by controlling an injected current region and is commercially widely used.

For a SWIR (Short Wave Infrared) wavelength band light source, a GaAs material base is required to be replaced with an InP material base. In the case of the InP material base, an oxide opening process through a wet process is difficult since it is challenging to grow a layer containing sufficient Al component due to lattice matching to InP.

Alternatively, a current flow area is limited by applying an ion-implantation method to an InP-based VCSEL process. Current does not flow in an area where ions have been injected but flows in an area where ions have not been injected so that current flows only within a desired area, thus making it possible to form a current opening. However, forming a current opening with a desired area at a particular depth through an ion-implantation method has low reproducibility and involves a complicated process.

### SUMMARY

The present disclosure provides a method for manufacturing a vertical-cavity surface-emitting laser device, by which current injection openings having various thicknesses and different sizes may be formed with a uniform size and at intended positions through a process performed once.

Disclosed is a method for manufacturing a vertical-cavity surface-emitting laser device. The method includes: forming epitaxy layers including an etch stop layer, a first reflective layer, a first spacer layer, and a dummy current restriction layer on a carrier substrate; forming a dummy current restriction pattern having an opening by partially removing the dummy current restriction layer using a photolithography process and an etching process; forming a second spacer layer in the opening and on the dummy current restriction pattern; bonding the second spacer layer onto a substrate having a second reflective layer; and removing the carrier substrate and the etch stop layer.

In an embodiment, the epitaxy layers may further include an active layer between the first spacer layer and the dummy current restriction layer, an electron barrier layer between the active layer and the dummy current restriction layer, and a tunnel junction layer between the electron barrier layer and the dummy current restriction layer. In an embodiment, the method may further include forming a mesa structure by sequentially and partially removing the first reflective layer, the first spacer layer, the active layer, the electron barrier layer, the tunnel junction layer, and the dummy current restriction pattern.

In an embodiment, the method may further include forming a sidewall opening by removing the dummy current restriction pattern.

In an embodiment, the method may further include forming a passivation layer on a sidewall of the mesa structure, wherein forming the passivation layer may include forming a current restriction pattern in the sidewall opening.

In an embodiment, forming the dummy current restriction pattern may include: forming a mask layer partially exposing the dummy current restriction layer; and forming the dummy current restriction pattern by partially removing the dummy current restriction layer exposed by the mask layer.

In an embodiment, the method may further include planarizing the second spacer layer.

In an embodiment, forming the epitaxy layers may include forming an additional spacer layer on the dummy current restriction layer.

In an embodiment, the method may further include forming an electron restriction pattern having an electron injection opening in the first spacer layer.

In an embodiment, forming the electron restriction pattern may include: forming a dummy electron restriction layer on the first reflective layer; forming a dummy electron restriction pattern having the electron injection opening by partially removing the dummy electron restriction layer using a photolithography process and an etching process; and forming the first spacer layer in the electron injection opening and on the dummy electron restriction pattern.

In an embodiment, forming the electron restriction pattern may include: forming a lower sidewall opening by removing the dummy electron restriction pattern exposed to a sidewall of the mesa structure; and forming the electron restriction pattern in the lower sidewall opening.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a flowchart illustrating a method for manufacturing a vertical-cavity surface-emitting laser device according to the inventive concept;

FIGS. 2 to 14 are cross-sectional views illustrating a manufacturing process of a vertical-cavity surface-emitting laser device of an embodiment of the inventive concept;

FIG. 15 is a cross-sectional view of an example of a vertical-cavity surface-emitting laser device according to the inventive concept;

FIG. 16 is a cross-sectional view of an example of a vertical-cavity surface-emitting laser device according to the inventive concept;

FIG. 17 is a cross-sectional view of an example of a vertical-cavity surface-emitting laser device according to the inventive concept;

FIG. 18 is a cross-sectional view of an example of a vertical-cavity surface-emitting laser device according to the inventive concept;

FIG. 19 is a plan view of an example of the current injection openings of FIG. 5;

FIG. 20 is a flowchart illustrating a method for manufacturing a vertical-cavity surface-emitting laser device according to the inventive concept;

FIGS. 21 to 26 are cross-sectional views illustrating a manufacturing process of a vertical-cavity surface-emitting laser device of an embodiment of the inventive concept; and

FIG. 27 is a cross-sectional view of an example of a vertical-cavity surface-emitting laser device according to the inventive concept.

### DETAILED DESCRIPTION

Embodiments of the inventive concept will now be described in detail with reference to the accompanying drawings. Advantages and features of embodiments of the inventive concept, and methods for achieving the advantages and features will be apparent from the embodiments described in detail below with reference to the accompanying drawings. However, the inventive concept may be embodied in different forms and should not be construed as limited to the embodiments set forth herein. Rather, these embodiments are provided so that this disclosure will be thorough and complete, and will fully convey the scope of the inventive concept to those skilled in the art, and the inventive concept is only defined by the scope of the claims. Like reference numerals refer to like elements throughout.

The terminology used herein is not for delimiting the embodiments of the inventive concept but for describing the embodiments. The terms of a singular form may include plural forms unless otherwise specified. The term “include,” “comprise,” “including” or “comprising” specifies an element, a step, an operation and/or an element but does not exclude other elements, steps, operations and/or elements. Furthermore, reference numerals, which are presented in the order of description, are provided according to the embodiments and are thus not necessarily limited to the order. In addition, in this description, when a certain film is referred to as being on another film or substrate, it can be directly on the other film or substrate, or a third film may be interposed therebetween.

The embodiments of the inventive concept will be described with reference to example cross-sectional views and/or plan views. In the drawings, the dimensions of layers and regions are exaggerated for clarity of illustration. Therefore, the forms of the example drawings may be changed due to a manufacturing technology and/or error tolerance. Therefore, the embodiments of the inventive concept may involve changes of shapes depending on a manufacturing process, without being limited to the illustrated specific forms. For example, a curved fluid and polymer layer may be formed flat. Therefore, the regions illustrated in the drawings are merely schematic, and the shapes of the regions exemplify specific shapes of the elements but do not limit the scope of the invention.

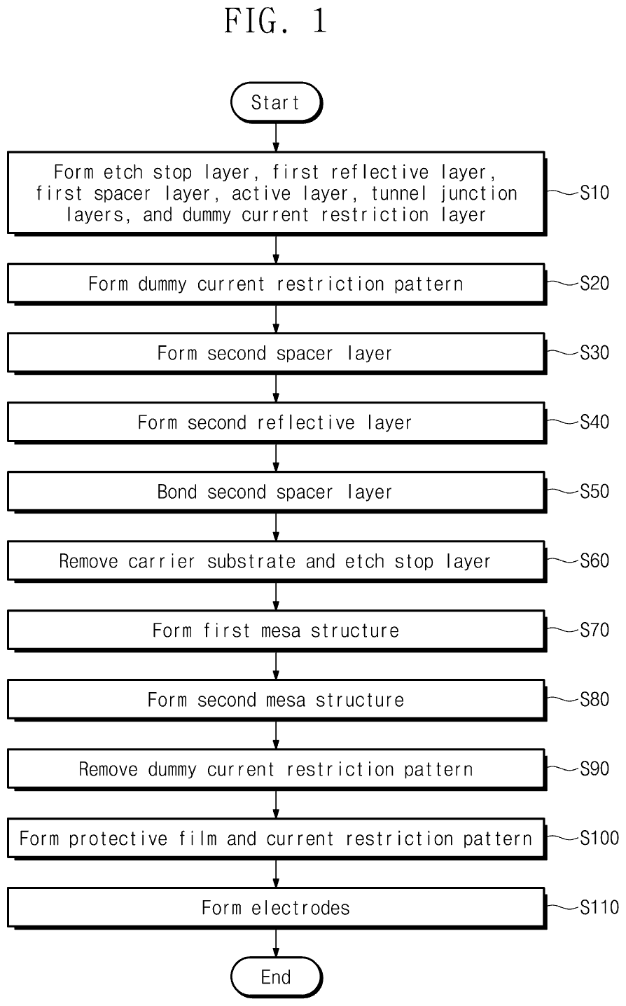

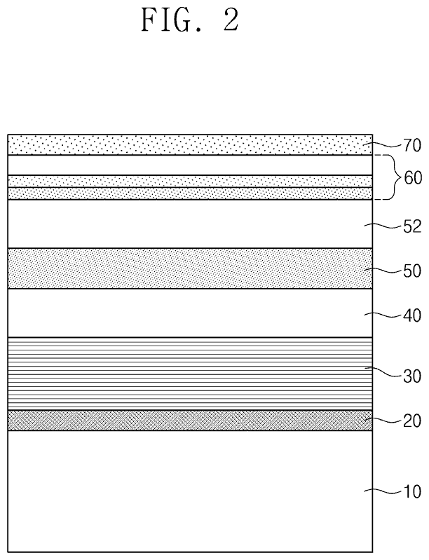

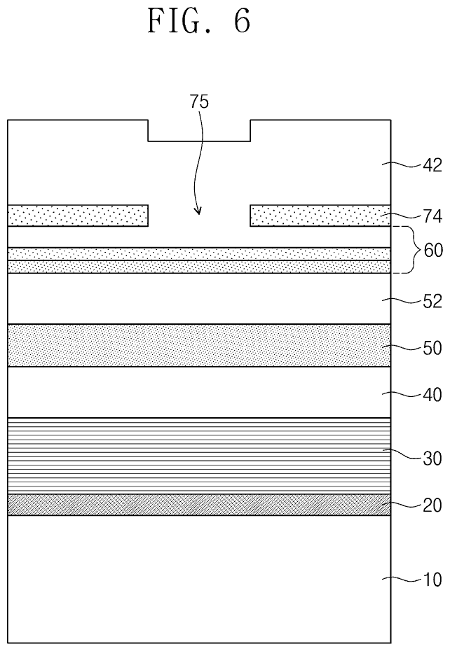

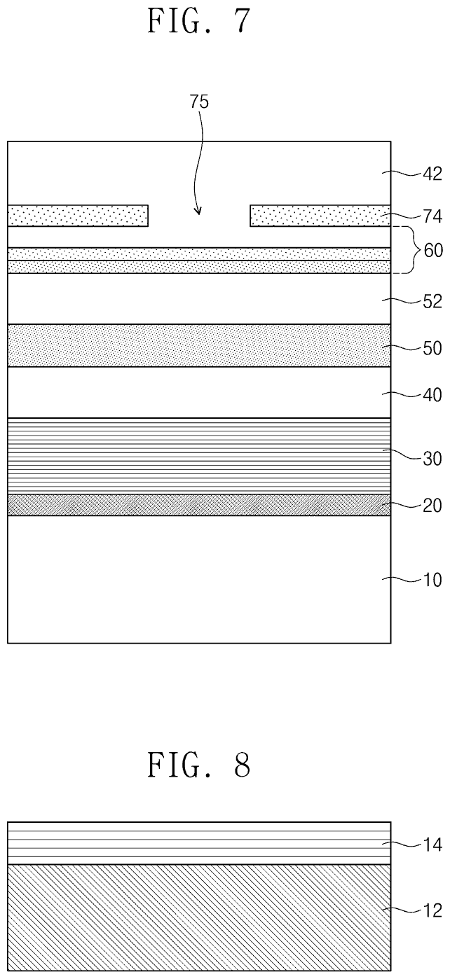

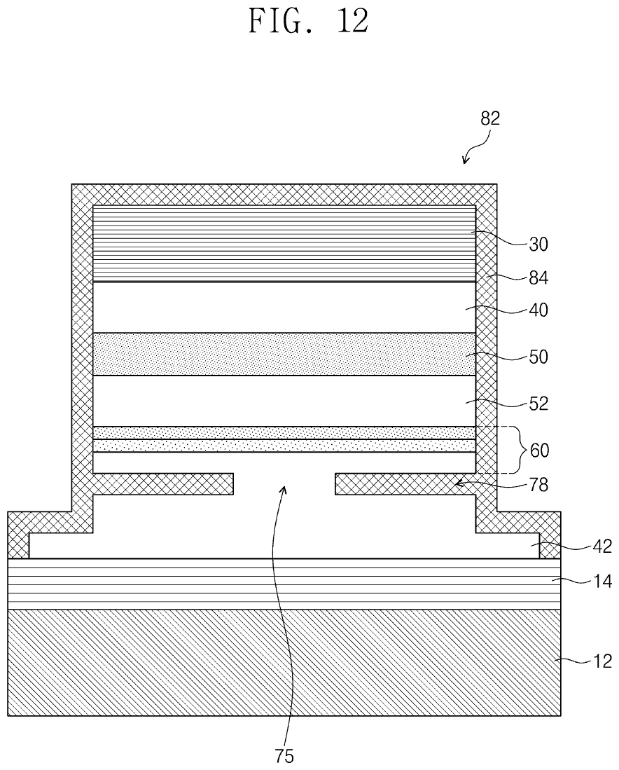

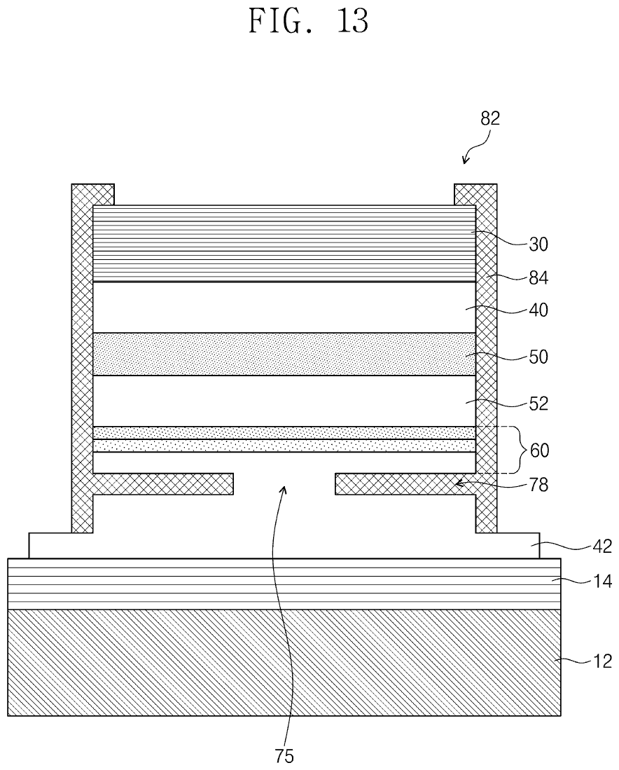

FIG. 1 illustrates a method for manufacturing a vertical-cavity surface-emitting laser device according to the inventive concept. FIGS. 2 to 14 are cross-sectional views illustrating a manufacturing process of a vertical-cavity surface-emitting laser device 100 of an embodiment of the inventive concept.

Referring to FIGS. 1 and 2, an etch stop layer 20, a first reflective layer 30, a first spacer layer 40, an active layer 50, an electron barrier layer 52, a tunnel junction layer 60, and a dummy current restriction layer 70 are formed on a carrier substrate 10 (S10).

The carrier substrate 10 may include InP. Alternatively, the carrier layer 10 may include GaAs, but an embodiment of the inventive concept is not limited thereto. The etch stop layer 20, the first reflective layer 30, the first spacer layer 40, the active layer 50, the electron barrier layer 52, the tunnel junction layer 60, and the dummy current restriction layer 70 may be lattice matched to the carrier substrate 10 and sequentially and expitaxially grown.

The etch stop layer 20, the first reflective layer 30, the first spacer layer 40, the active layer 50, the electron barrier layer 52, the tunnel junction layer 60, and the dummy current restriction layer 70 may be epitaxy layers.

The etch stop layer 20 may be formed on the carrier substrate 10. In the case where the carrier substrate 10 includes InP, the etch stop layer 20 may include InGaAs. The etch stop layer 20 may have an etch selectivity with respect to InP and include a material having a different lattice constant from the lattice constant of the InP, but an embodiment of the inventive concept is not limited thereto.

The first reflective layer 30 may be formed on the etch stop layer 20. The first reflective layer 30 may include an n-type doped semiconductor distributed Bragg reflector layer. For example, the first reflective layer 30 may include a laminate structure of InAlGaAs/InAlAs or InP/InAlGaAs. Alternatively, the first reflective layer 30 may not be doped.

The first spacer layer 40 may be formed on the first reflective layer 30. For example, the first spacer layer 40 may include n-type InP.

The active layer 50 may be formed on the first spacer layer 40. The active layer 50 may include multi quantum well layers. The multi quantum well layers may include InAlGaAs or InGaAsP. Although not illustrated, the active layer 50 may further include barrier layers laminated alternately with the multi quantum well layers. The barrier layers may include at least one of InP, InAlAs, InGaAlAs, or InGaAs.

The electron barrier layer 52 may be formed on the active layer 50. For example, the electron barrier layer 52 may include p-type InAlAs.

The tunnel junction layers 60 may be formed on the electron barrier layer 52. For example, the tunnel junction layers 60 may include a laminate structure of a p⁺⁺-type InP layer, n⁺⁺-type InAlAs layer, and n-type InP.

The dummy current restriction layer 70 may be formed on the tunnel junction layers 60. For example, the dummy current restriction layer 70 may include InGaAs.

Referring to FIGS. 1 and 3 to 5, a dummy current restriction pattern 74 is formed by partially removing the dummy current restriction layer 70 (S20). The dummy current restriction pattern 74 may be patterned so as to have a current injection opening 75 through a photolithography process and etching process.

Hereinafter, a method for patterning the dummy current restriction pattern 74 will be described.

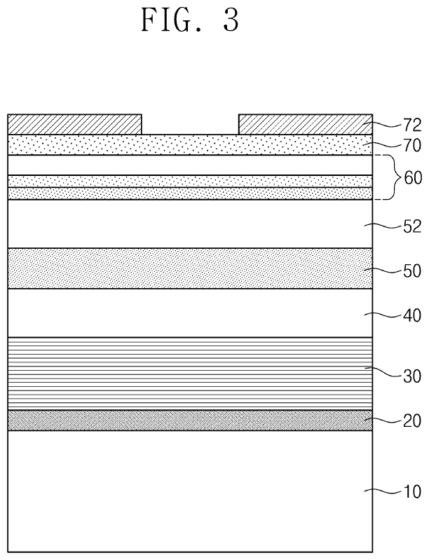

Referring to FIG. 3, a mask layer 72 is formed on the dummy current restriction layer 70. The mask layer 72 may include a photoresist pattern formed through a photolithography process. The mask layer 72 may be patterned so as to partially expose the dummy current restriction layer 70. Alternatively, the mask layer 72 may include a hard mask layer such as a silicon nitride layer or silicon oxide layer, but an embodiment of the inventive concept is not limited thereto.

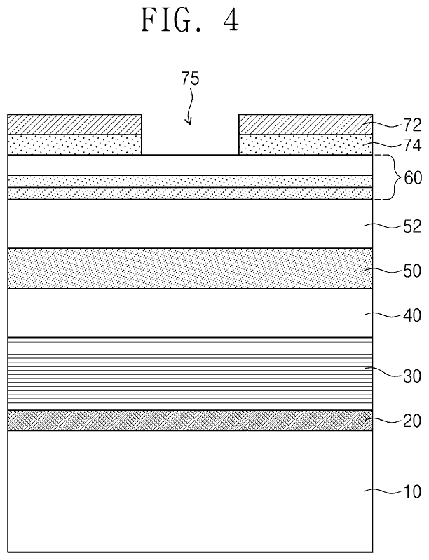

Referring to FIG. 4, the current injection opening 75 of the dummy current restriction pattern 74 is formed by partially removing the dummy current restriction layer 70 using the mask layer 72 as an etching mask. A shape, size, thickness, and position of the current injection opening 75 may vary according to a purpose of use of the vertical-cavity surface-emitting laser device.

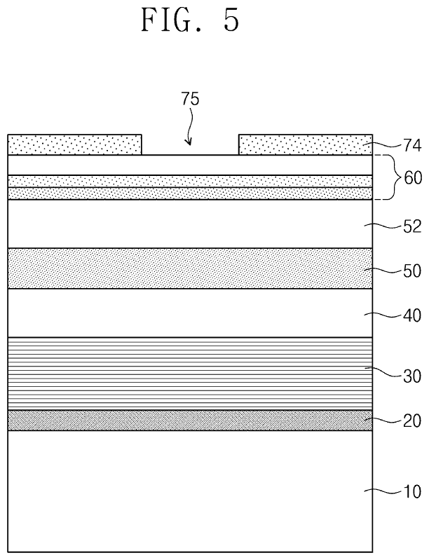

Referring to FIG. 5, the mask layer 72 is removed. The mask layer 72 may be removed using an organic solvent. The mask layer 72 that is a hard mask layer may be removed through a wet etching process or dry etching process.

Referring to FIGS. 1, 6, and 7, a second spacer layer 42 is formed in the current injection opening 75, and on the dummy current restriction layer 70 (S30). The second spacer layer 42 may have an uneven upper surface. Furthermore, the second spacer layer 42 may be planarized through a chemical mechanical polishing (CMP) method.

Therefore, a method for manufacturing the vertical-cavity surface-emitting laser device 100 of an embodiment of the inventive concept may form the current injection opening 75 of the dummy current restriction pattern 74 with a regular size.

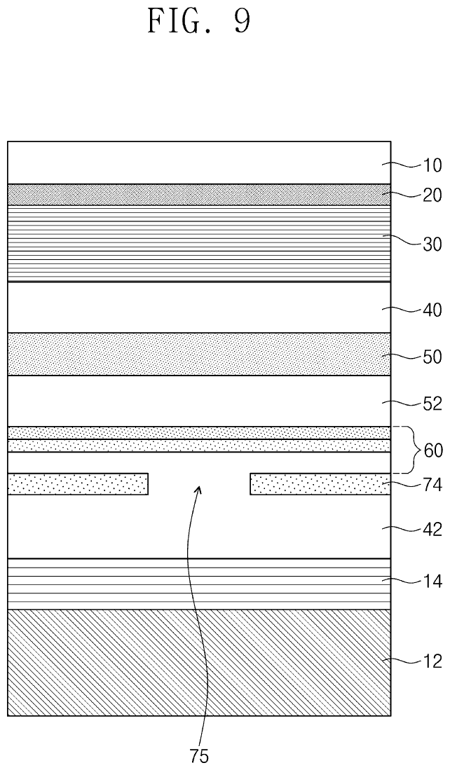

Referring to FIGS. 1 and 8, a second reflective layer 14 is formed on a substrate 12 (S40). The substrate 12 may include a silicon wafer. Alternatively, the substrate 12 may include a glass substrate or silicon carbide substrate, but an embodiment of the inventive concept is not limited thereto. The second reflective layer 14 may include a laminate structure of silicon oxide/amorphous silicon. The silicon oxide/amorphous silicon may have a thickness of λ (resonance wavelength)/4n (refractive index). The second reflective layer 14 may be formed through a plasma-enhanced chemical vapor deposition (PECVD) or sputtering process.

Referring to FIGS. 1 and 9, the second spacer layer 42 is bonded to the second reflective layer 14 (S50).

The second spacer layer 42 may be heterogeneously bonded through a direct wafer bonding method or ultra-thin bisbenzocyclobutene (BCB) bonding method. Although not illustrated, an alumina (Al₂O₃) or silicon oxide layer (SiO₂) may be provided between the second spacer 42 and the second reflective layer 14.

Next, the carrier substrate 10 and the etch stop layer 20 are removed (S60). The carrier substrate 10 and the etch stop layer 20 may be removed through a wet etching process.

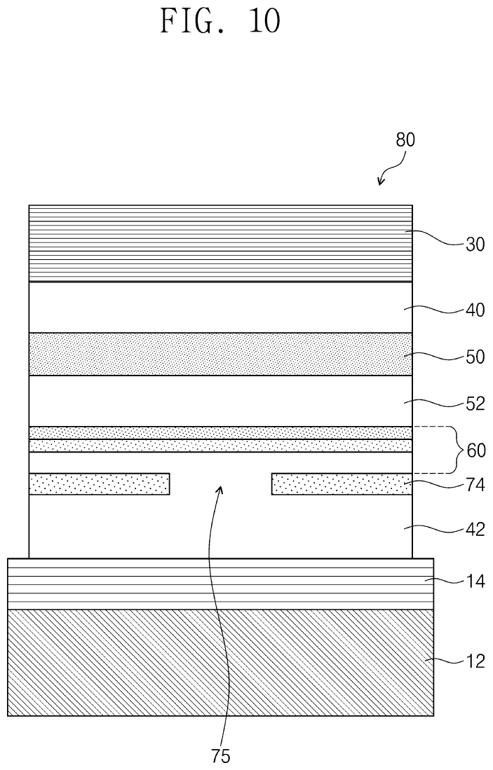

Referring to FIGS. 1 and 10, a first mesa structure 80 is formed by partially removing the first reflective layer 30, the first spacer layer 40, the active layer 50, the electron barrier layer 52, the tunnel junction layer 60, the dummy current restriction pattern 74, and the second spacer layer 42 (S70). The first mesa structure 80 may partially expose an edge of the second reflective layer 14. The first reflective layer 30, the first spacer layer 40, the active layer 50, the electron barrier layer 52, the tunnel junction layer 60, the dummy current restriction pattern 74, and the second spacer layer 42 may be removed through a dry etching process or wet etching process.

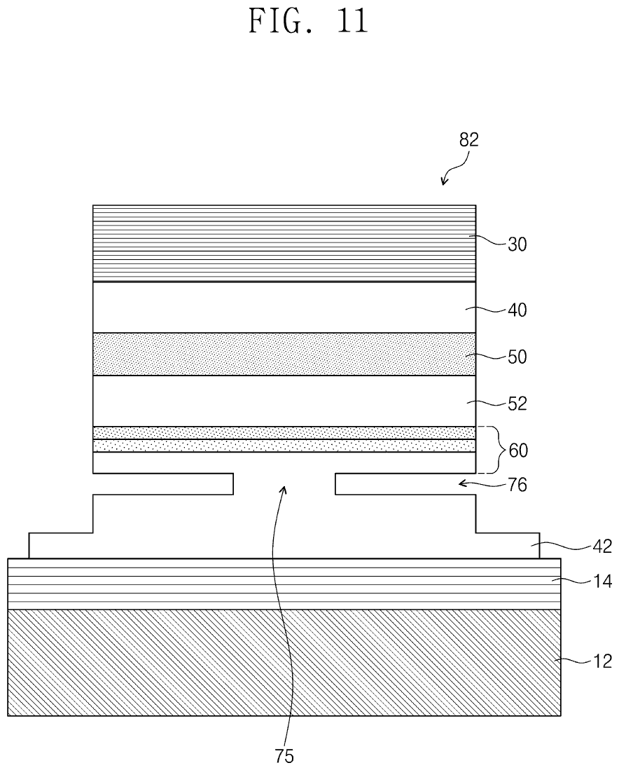

Referring to FIGS. 1 and 11, a second mesa structure 82 is formed by further partially removing the first reflective layer 30, the first spacer layer 40, the active layer 50, the electron barrier layer 52, the tunnel junction layer 60, the dummy current restriction pattern 74, and the second spacer layer 42 (S80). The second mesa structure 82 may partially expose an edge of the second spacer layer 42.

Next, a side opening 76 is formed by removing the dummy current restriction pattern 74 (S90). The dummy current restriction pattern 74 may be removed through a wet etching process. The side opening 76 may be formed on an outer periphery of the current injection opening 75.

Referring to FIGS. 1, 12, and 13, a passivation layer 84 and a current restriction pattern 78 are formed on an outer circumferential surface of the second mesa structure 82 (S100). The passivation layer 84 may be formed on a sidewall and corner of the second mesa structure 82. The current restriction pattern 78 may be formed in the side opening 76. The passivation layer 84 and the current restriction pattern 78 may include a dielectric layer formed through an atomic layer deposition method. For example, the passivation layer 84 and the current restriction pattern 78 may include Al₂O₃ or SiO₂. The passivation layer 84 may be patterned so as to expose a center portion of the first reflective layer 30 and an edge of the second spacer layer 42.

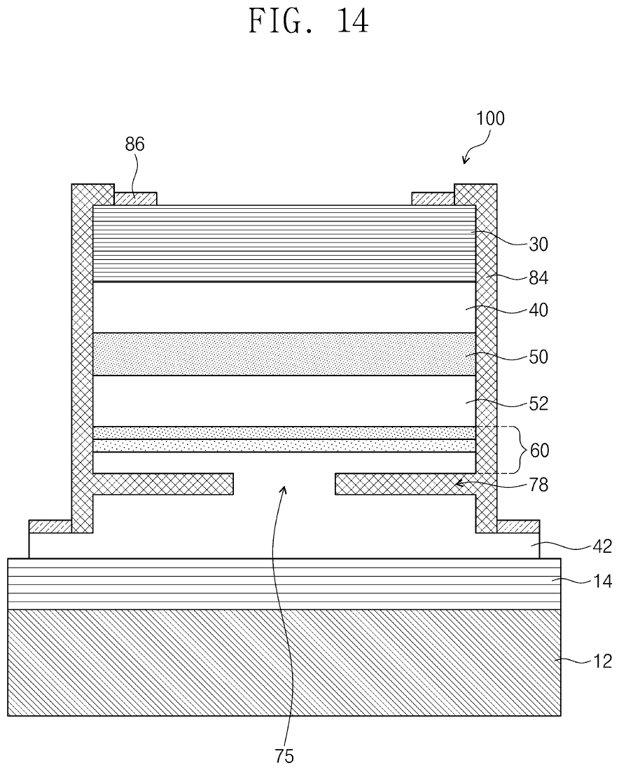

Referring to FIGS. 1 and 14, electrodes 86 are formed on an edge of the first reflective layer 30 and an edge of the second spacer layer 42 (S110). The electrodes 86 may be formed through a metal vapor deposition process, a photolithography process, and an etching process.

Therefore, a method for manufacturing the vertical-cavity surface-emitting laser device 100 of an embodiment of the inventive concept may form multiple current injection openings 75 with an intended shape, thickness, and size at desired positions regardless of wet etching process time by using a photolithography process. The vertical-cavity surface-emitting laser device 100 may have an InP material-based long-wavelength epitaxy structure and generate long-wavelength laser light.

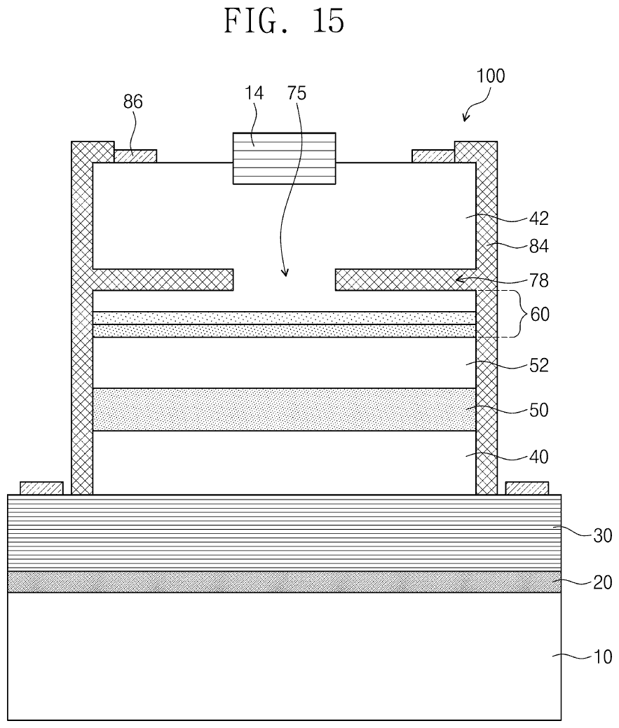

FIG. 15 illustrates an example of the vertical-cavity surface-emitting laser device 100 according to the inventive concept.

Referring to FIG. 15, the vertical-cavity surface-emitting laser device 100 of an embodiment of the inventive concept may include the second reflective layer 14 on a center of the second spacer layer 42 provided on the carrier substrate 10.

The electrodes 86 may be provided on edges of the second spacer layer 42 and the first reflective layer 30.

The etch stop layer 20 may be provided between the carrier substrate 10 and the first reflective layer 30. The first spacer layer 40 may be provided on the first reflective layer 30. The active layer 50 may be provided on the first reflective layer 30. The electron barrier layer 52 may be provided on the active layer 50. The tunnel junction layer 60 may be provided on the electron barrier layer 52. The current restriction pattern 78 may be provided on the tunnel junction layers 60. The second spacer layer 42 may be provided on the current restriction pattern 78. The passivation layer 84 may be provided on portions of sidewalls and edges of the first spacer layer 40, the active layer 50, the electron barrier layer 52, the tunnel junction layer 60, the current restriction pattern 78, and the second spacer layer 42.

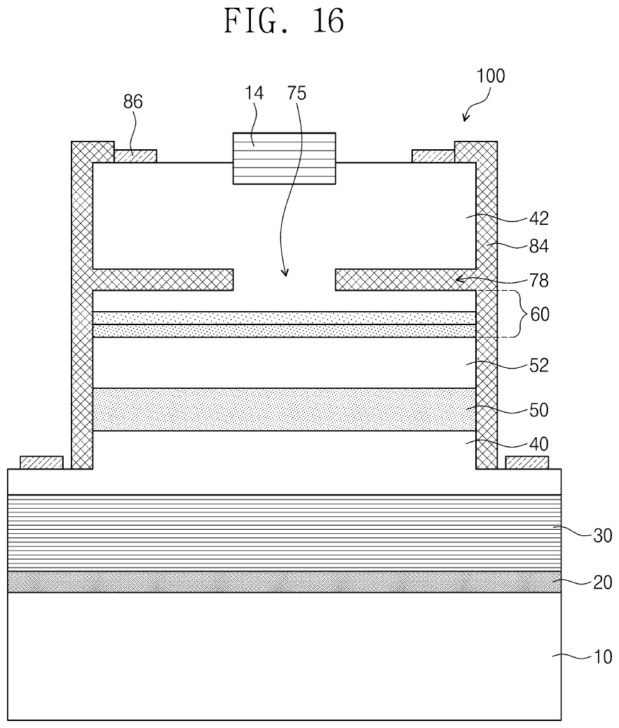

FIG. 16 illustrates an example of the vertical-cavity surface-emitting laser device 100 according to the inventive concept.

Referring to FIG. 16, portion of the electrodes 86 may be provided on an edge of the second spacer layer 40.

The carrier substrate 10, the etch stop layer 20, the first reflective layer 30, the active layer 50, the electron barrier layer 52, the tunnel junction layers 60, the current restriction pattern 78, the second spacer layer 42, and the passivation layer may be configured in the same manner as illustrated in FIG. 15.

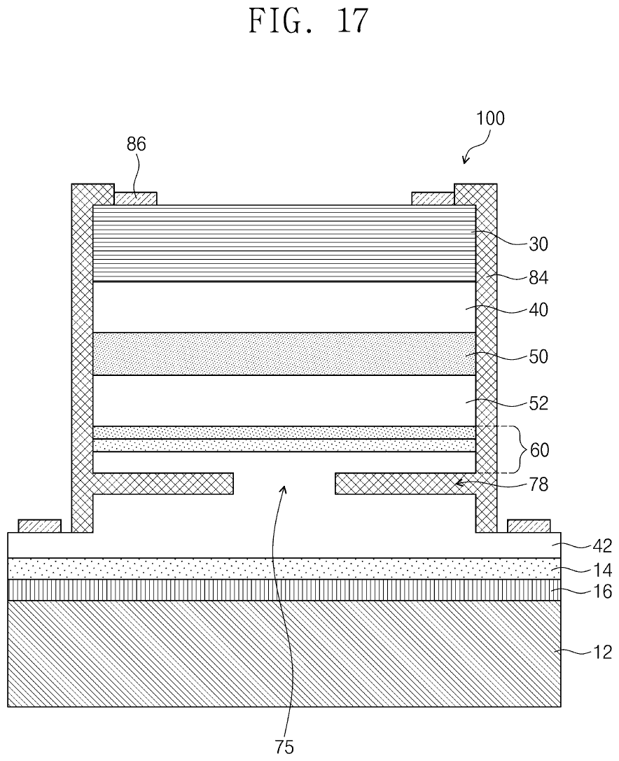

FIG. 17 illustrates an example of the vertical-cavity surface-emitting laser device 100 according to the inventive concept.

Referring to FIG. 17, the vertical-cavity surface-emitting laser device 100 of an embodiment of the inventive concept may further include an HCG mirror layer 16 between the substrate 12 and the second reflective layer 14. The substrate 12 may include a glass substrate. The second reflective layer 14 may include a low-refractive material layer.

The second spacer layer 42, the current restriction pattern 78, the tunnel junction layers 60, the electron barrier layer 52, the active layer 50, the first reflective layer 30, the electrodes 86, and the passivation layer 84 may be configured in the same manner as illustrated in FIG. 14.

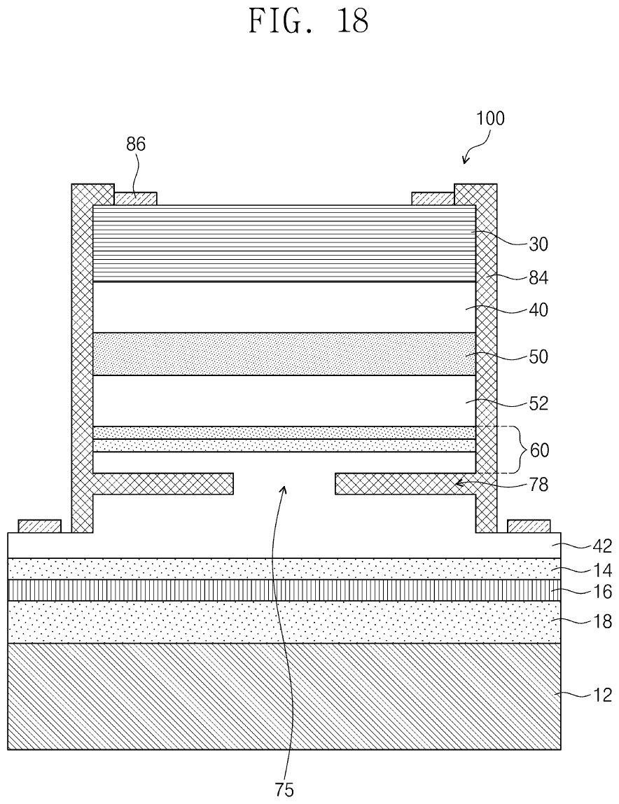

FIG. 18 illustrates an example of the vertical-cavity surface-emitting laser device 100 according to the inventive concept.

Referring to FIG. 18, the substrate 10 of the vertical-cavity surface-emitting laser device 100 of an embodiment of the inventive concept may include an SOI substrate. For example, the vertical-cavity surface-emitting laser device 100 may further include an HCG mirror layer 16 and an insulating layer 18 between the substrate 10 and the second reflective layer 14. The HCG mirror layer 16 may be provided on the insulating layer 18 that is a dielectric.

The second spacer layer 42, the current restriction pattern 78, the tunnel junction layers 60, the electron barrier layer 52, the active layer 50, the first reflective layer 30, the electrodes 86, and the passivation layer 84 may be configured in the same manner as illustrated in FIG. 14.

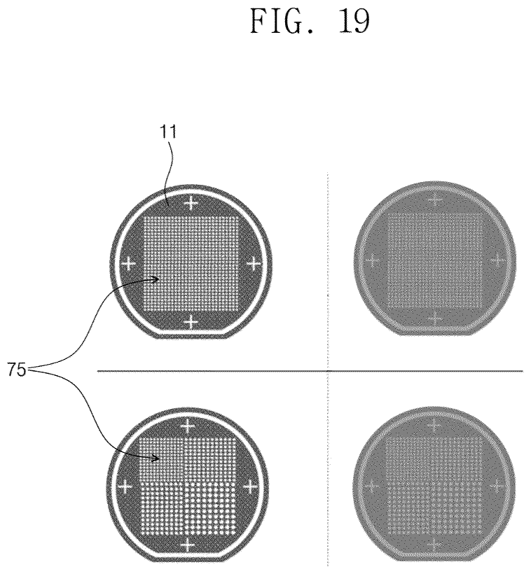

FIG. 19 illustrates examples of the current injection openings 75 of FIG. 5.

Referring to FIG. 19, the current injection openings 75 may have a uniform size or a plurality of different sizes. Furthermore, the current injection openings 75 may have various shapes without being limited to a circular shape.

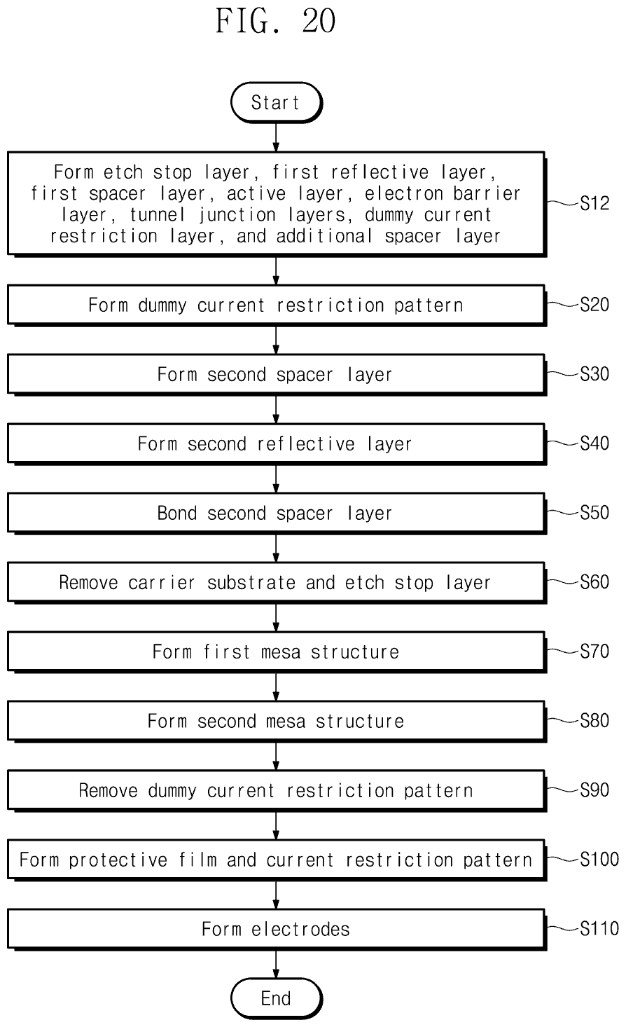

FIG. 20 illustrates a method for manufacturing the vertical-cavity surface-emitting laser device 100 according to the inventive concept.

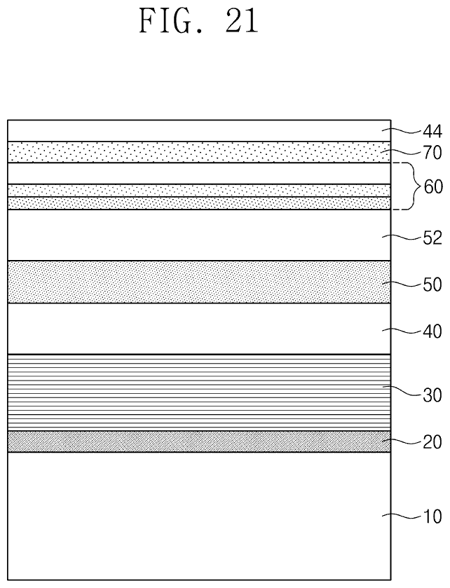

FIGS. 21 to 26 are cross-sectional views illustrating a manufacturing process of the vertical-cavity surface-emitting laser device 100 of an embodiment of the inventive concept.

Referring to FIGS. 20 and 21, the etch stop layer 20, the first reflective layer 30, the first spacer layer 40, the active layer 50, the electron barrier layer 52, the tunnel junction layer 60, the dummy current restriction layer 70, and an additional spacer layer 44 are formed on the carrier substrate 10 (S10). The etch stop layer 20, the first reflective layer 30, the first spacer layer 40, the active layer 50, the electron barrier layer 52, the tunnel junction layer 60, and the dummy current restriction layer 70 on the carrier substrate 10 may be configured in the same manner as illustrated in FIG. 2. The additional spacer layer 44 may be formed on the dummy current restriction layer 70. The additional spacer layer 44 may include n-type InP.

Referring to FIGS. 20 and 22 to 24, the dummy current restriction pattern 74 is formed by partially removing the additional spacer layer 44 and the dummy current restriction layer 70 using the mask layer 72 of a photolithography process (S20).

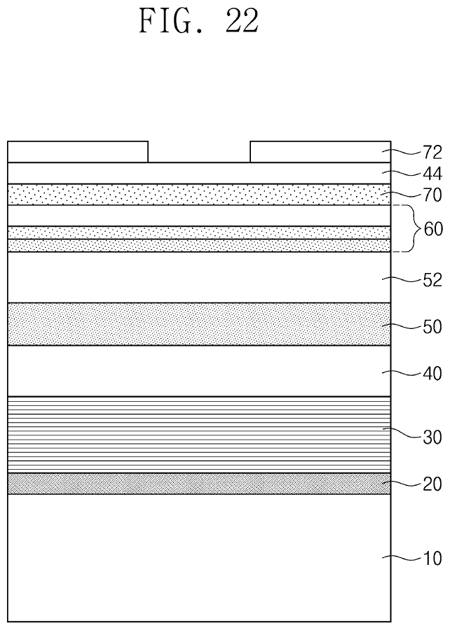

Referring to FIG. 22, the mask layer 72 may partially expose the additional spacer layer 44.

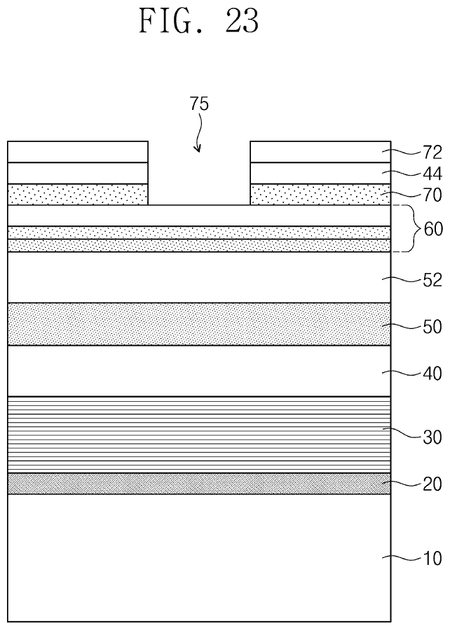

Referring to FIG. 23, the current injection opening 75 is formed by partially removing the dummy current restriction layer 70 and the additional spacer layer 44 exposed by the mask layer 72.

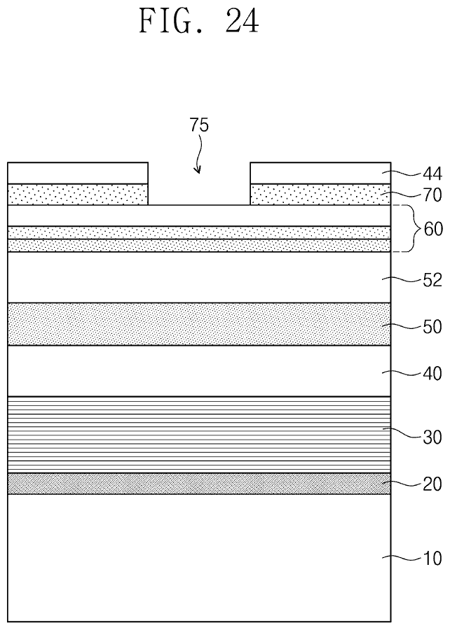

Referring to FIG. 24, the mask layer 72 may be removed. The mask layer 72 may be removed through a cleaning process using an organic solvent.

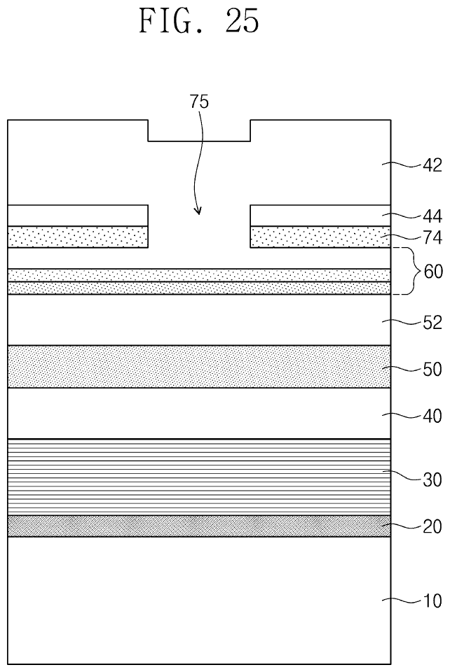

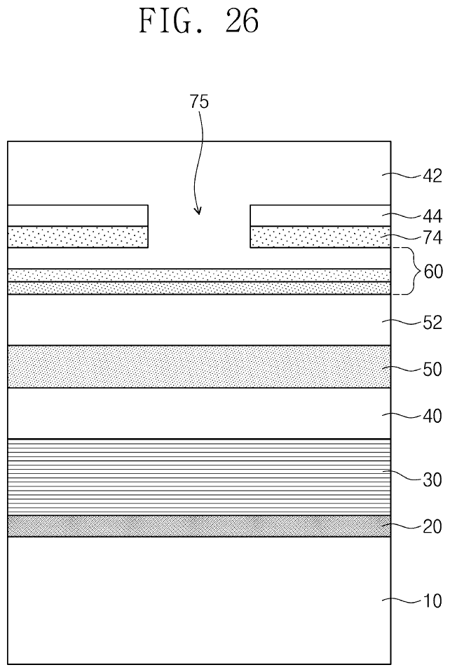

Referring to FIGS. 25 and 26, the second spacer layer 42 is formed in the current injection opening 75 and on the additional spacer layer 44 (S30). The second spacer layer 42 may be planarized.

Steps S40 to S110 may be configured in the same manner as illustrated in FIG. 1.

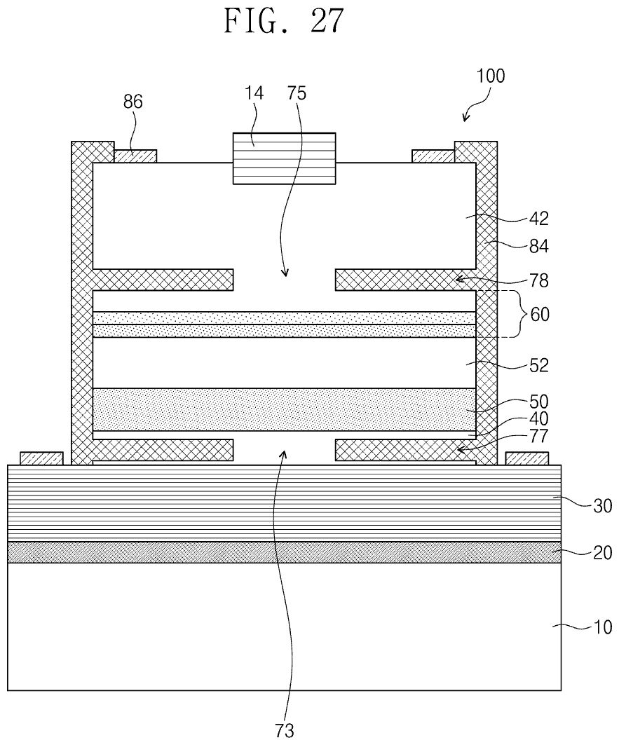

FIG. 27 illustrates an example of the vertical-cavity surface-emitting laser device 100 according to the inventive concept.

Referring to FIG. 27, the vertical-cavity surface-emitting laser device 100 of an embodiment of the inventive concept may further include an electron restriction pattern 77 in a lower portion.

The electron restriction pattern 77 may be provided in the first spacer layer 40. The electron restriction pattern 77 may be provided between the active layer 50 and the first reflective layer 30. An amount and/or direction of electrons provided to the active layer 50 may be adjusted by adjusting a shape, size, and thickness of the electron restriction pattern 77. According to an example, the electron restriction pattern 77 may have an electron injection opening 73. The electron injection opening 73 may be aligned with the current injection opening 75. That is, the electron injection opening 73 may have a diameter that is the same as or different from a diameter of the current injection opening 75. The electron injection opening 73 may further define the amount and/or direction of electrons.

Although not illustrated, the electron restriction pattern 77 may have the electron injection opening 73 formed through a photolithography process and etching process for a dummy electron restriction layer. The dummy electron restriction layer may be formed as a dummy electron restriction pattern having the electron injection opening 73 on the first reflective layer 30. The first spacer layer 40 may be formed in the electron injection opening 73 and in the dummy electron restriction pattern. The dummy electron restriction pattern may be exposed to a sidewall of the second mesa structure 82 and removed by a wet etching solution so as to be formed as a lower sidewall opening. The electron restriction pattern 77 may be formed in the lower sidewall opening simultaneously with the passivation layer 84.

The carrier substrate 10, the etch stop layer 20, the first reflective layer 30, the active layer 50, the electron barrier layer 52, the tunnel junction layers 60, the current restriction pattern 78, the second spacer layer 42, the second reflective layer 14, the passivation layer 84, and the electrodes 86 may be configured in the same manner as illustrated in FIG. 16.

As described above, a method for manufacturing a vertical-cavity surface-emitting laser device according to an embodiment of the inventive concept may form a current injection opening with a regular size by partially removing a dummy current restriction layer using a photolithography process and an etching process.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A method for manufacturing a vertical-cavity surface-emitting laser device, the method comprising:
forming epitaxy layers including an etch stop layer, a first reflective layer, a first spacer layer, and a dummy current restriction layer on a carrier substrate;
forming a dummy current restriction pattern having an opening by partially removing the dummy current restriction layer using a photolithography process and an etching process;
forming a second spacer layer in the opening and on the dummy current restriction pattern;
bonding the second spacer layer onto a substrate having a second reflective layer; and
removing the carrier substrate and the etch stop layer.

2. The method of claim 1,
wherein the epitaxy layers further include an active layer between the first spacer layer and the dummy current restriction layer, an electron barrier layer between the active layer and the dummy current restriction layer, and a tunnel junction layer between the electron barrier layer and the dummy current restriction layer,
wherein the method further comprises forming a mesa structure by sequentially and partially removing the first reflective layer, the first spacer layer, the active layer, the electron barrier layer, the tunnel junction layer, and the dummy current restriction pattern.

3. The method of claim 2, further comprising forming a sidewall opening by removing the dummy current restriction pattern.

4. The method of claim 3, further comprising
forming a passivation layer on a sidewall of the mesa structure,
wherein forming the passivation layer includes forming a current restriction pattern in the sidewall opening.

5. The method of claim 1, wherein forming the dummy current restriction pattern includes:
forming a mask layer partially exposing the dummy current restriction layer; and
forming the dummy current restriction pattern by partially removing the dummy current restriction layer exposed by the mask layer.

6. The method of claim 1, further comprising planarizing the second spacer layer.

7. The method of claim 1, wherein forming the epitaxy layers includes forming an additional spacer layer on the dummy current restriction layer.

8. The method of claim 1, further comprising forming an electron restriction pattern having an electron injection opening in the first spacer layer.

9. The method of claim 8, wherein forming the electron restriction pattern includes:
forming a dummy electron restriction layer on the first reflective layer;
forming a dummy electron restriction pattern having the electron injection opening by partially removing the dummy electron restriction layer using a photolithography process and an etching process; and
forming the first spacer layer in the electron injection opening and on the dummy electron restriction pattern.

10. The method of claim 9, wherein forming the electron restriction pattern includes:
forming a lower sidewall opening by removing the dummy electron restriction pattern exposed to a sidewall of the mesa structure; and
forming the electron restriction pattern in the lower sidewall opening.
